(19) United States
(12) Patent Application Publication
(10) Pub. No.: US 2005/0126904 A1
(43) Pub. Date: Jun. 16, 2005

(54) Apparatus and process for physical vapor deposition

(76) Inventor: Tai-Yuan Chen, Changhua City (TW)

Correspondence Address: J C PATENTS, INC., 4 VENTURE, SUITE 250, IRVINE, CA, 92618, US

(21) Appl. No.: 10/930,239

(22) Filed: Aug. 30, 2004

(30) Foreign Application Priority Data
Dec. 16, 2003 (TW) 92135520

(51) Int. Cl. C23C 14/32

(52) U.S. Cl. 204/192.12; 204/298.2; 204/298.19

(57) ABSTRACT

An apparatus for physical vapor deposition (PVD) is described. The apparatus includes a chamber, a target back plate, a wafer base, a target and a mobile magnetron device. The target back plate is located over a top surface of the chamber, and the wafer base is located over a bottom surface of the chamber. The target is located over a surface of the target back plate facing the wafer base. Further, the mobile magnetron device is located outside the chamber and above the target. The PVD apparatus can be used that the distance between a magnetic pole of the mobile magnetron device and a bombardment surface of the target is kept constant by adjusting the position of the mobile magnetron device. Therefore, the intensity of magnetic field induced throughout the bombardment surface of the target can also be maintained at a constant value.

### CROSS-REFERENCE TO RELATED APPLICATION

This application claims the priority benefit of Taiwan application serial no. 92135520, filed on Dec. 16, 2003.

### BACKGROUND OF THE INVENTION

1. Field of the Invention

The present invention relates to an apparatus and process for fabricating semiconductors. More specifically the present invention relates to an apparatus and process for physical vapor deposition (PVD).

2. Description of Related Art

The common techniques available for forming a film over a semiconductor wafer are physical vapor deposition (PVD) and chemical vapor deposition (CVD). The PVD process can be further classified into an evaporation process and sputtering process. PVD using the evaporation process is carried out by heating an evaporation source to generate a saturated vapor pressure, and then depositing the generated vapor onto a surface of a wafer to form a film over the wafer. PVD using the sputtering process, on the other hand, is performed by bombarding a target with ions generated from plasma, and then depositing the sputtered atoms onto a wafer to form a film over the wafer.

In the sputtering process, generation of plasma closely relates to the amount of plasma ions (e.g., argon ions) bombarding the target. In other words, the probability of collision between the plasma ions and the high-energy electrons of the target affects the performance of the sputtering process significantly. Thus, in order to increase the probability (also called sputtering yield) of ionization of gaseous atoms of the plasma, the distance that electrons pass before disappearing from the plasma is increased. Conventionally, a magnetron sputtering process is used, wherein a rotating magnetron device is disposed above a target in a plasma chamber. This arrangement of the rotating magnetron device affects the movement of charged electrons via a magnetic field generated by the magnetron device, and further deviates the route of the charged electrons, making them move in a spiral manner. Therefore, the use of the magnetron device increases the probability of collision of the plasma gaseous atoms and the target, and hence increases the sputtering yield. As a result of increased sputtering yield, the vacuum needed for operating the magnetron plasma is kept at a level lower than that required in conventional DC plasma, and further the characteristics of the deposited film can be controlled.

However, since the magnetron device is disposed at a fixed position over the target, the thickness of the target is reduced gradually through the process of deposition. Consequently, the distance between the surface of the target and the magnetron device is also gradually reduced. This causes problems due to gradually increasing magnetic field intensity induced on the bombarded surface of the target and further intensifying asymmetry of the asymmetric deposition as shown in FIG. 1. FIG. 1 illustrates a film deposited in a trench portion in a lithographic alignment or overlap mark on a wafer using a conventional magnetron DC sputtering process. As illustrated in FIG. 1, the magnetic field intensity induced on a bombardment surface of a target affects the sputtering angle at which plasma ions are sputtered onto the target. Not maintaining the same magnetic field intensity induced throughout the bombardment surface of the target causes the problem of asymmetric deposition of film 102 on the sidewalls of opening 104 in wafer 100. In addition, a shifting of film 102 is caused by such asymmetric deposition. The shift directions are different for film 102 deposited at different locations on wafer 100. In other words, the problem caused by different magnetic field intensity induced on the bombardment surface of the target affects the shift trajectory of plasma ions, and further causes the problem of a rotational shift of deposited film 102 on wafer 100. This rotational shift is indicated by reference arrows 106.

Also, aluminum conductive lines in a process of fabricating an interconnection can be made using a magnetron DC sputtering method. To ensure accurate alignment of the aluminum conductive lines with contact windows or plugs in the underlying layer, after a layer of aluminum conductive materials is deposited on the wafer entirely, alignment mark and overlap mark are measured and compared with respect to a photoresist layer before an exposure step and after an etching step. When a rotational shift exists, an adjustment needs to be made in the next exposure of the photoresist layer that defines the aluminum conductive lines. The alignment or overlap mark is measured according to the difference in brightness shown as a result of the difference in the height of the marks. Hence, the central point measured based on the difference in height of the surfaces in a trench, will have a rotational shift when metal is deposited asymmetrically on two sidewalls of the trench. Moreover, the rotational shift due to asymmetric deposition will increase with the consumption of the target. Even though such a problem of rotational shift may be solved through certain methods of adjustment, those methods are not effective since each deposition device and each shift situation is unique.

### SUMMARY OF THE INVENTION

In view of the above, one object of the present invention is to provide a PVD apparatus in which the electric field intensity induced on a bombardment surface of a target can be kept substantially same and thus a film can be deposited with the same extent of asymmetric deposition.

It is another object of the present invention to provide a PVD apparatus and process such that the asymmetry of the asymmetric deposition of a film can be kept substantially same on the sidewall of an opening in the deposited film.

In accordance with the above objects and other advantages of the present invention, as broadly embodied and described herein, the present invention provides an apparatus for PVD. In accordance with one embodiment of the present invention the PVD apparatus comprises a chamber, a target back plate, a wafer base, a target and a mobile magnetron device. The target back plate is disposed over a top surface of the chamber, while the wafer base is disposed over a bottom surface of the chamber. In addition, the target is disposed over a surface of the target back plate facing the wafer base. Further, the mobile magnetron device is disposed outside the chamber and above the target such that, during a PVD process, position of the magnetron device can be adjusted to maintain a constant distance between a magnet of the mobile magnetron device and a bombardment surface of the target.

In accordance with another embodiment of the present invention, the PVD apparatus comprises, a chamber, a target back plate, a wafer base, a target and an electromagnet-type magnetron device. The target back plate is disposed over a top surface of the chamber, while the wafer base is disposed over a bottom surface of the chamber. In addition, the target is disposed over a surface of the target back plate facing the wafer base. Further, the electromagnet-type magnetron device is disposed outside the chamber and above the target such that, during a PVD process, current intensity of the magnetron device can be adjusted so that the electric field intensity induced on a bombardment surface of the target can be kept substantially same.

It is yet another objective of the present invention to provide a process for performing PVD. The PVD process in accordance with one embodiment of the present invention comprises, first, providing a plasma chamber. The plasma chamber comprises a mobile magnetron device, a target, a target back plate, a wafer base, and a power supply device. The target is disposed on a surface of the target back plate facing the wafer base, the mobile magnetron device is disposed outside the plasma chamber and above the target, and the target back plate is electrically connected with the power supply device. Next, a wafer is placed on the wafer base, and then the power supply device is turned on to start the mobile magnetron device for depositing a film on the wafer. During the PVD process, position of the magnetron device can be adjusted to maintain a constant distance between a magnet of the mobile magnetron device and a bombardment surface of the target.

The PVD process in accordance with another embodiment of the present invention comprises providing a plasma chamber. The plasma chamber comprises an electromagnet-type magnetron device, a target, a target back plate, a wafer base, and a power supply device. The target is disposed on a surface of the target back plate facing the wafer base, the magnet-type magnetron device is disposed outside the plasma chamber and above the target, and the target back plate is electrically connected with the power supply device. Next, a wafer is placed on the wafer base, and then the power supply device is turned on to start the electromagnet-type magnetron device for depositing a film on the wafer. During the PVD process, current intensity of the electromagnet-type magnetron device can be adjusted in order to maintain a constant electric field intensity induced throughout the bombardment surface of the target.

A PVD process in accordance with yet another embodiment of the present invention comprises generating, an electric field and a magnetic field in a plasma reaction chamber for commencing a process of deposition. During the PVD process, intensity of the electric field is E, intensity of the magnetic field induced on a bombardment surface is B, electric charge carried by a plasma ion is q, mass of the plasma ion is m, and the velocity of the plasma ion is v. The relationship among q, m, v, E and B is illustrated by the following equation:
\vec{F}=q/m(\vec{E}+\vec{v}×\vec{B})
where, F is Lorentz force exerted on a plasma ion on the bombardment surface of the target. During the process of deposition, the Lorentz force (F) is maintained at a constant value.

The PVD apparatus described in the present invention comprises a mobile or electromagnet-type magnetron device. Thus, when it is used to carry out a PVD process, position of the mobile magnetron device or the current intensity of the electromagnet-type magnetron device can be adjusted in order to maintain a constant magnetic field intensity induced throughout a bombardment surface of the target, and further keep a constant Lorentz force exerted on plasma ions on the bombardment surface. Thus, the apparatus and process described in the present invention can keep the extent of asymmetry of the asymmetric deposition at a fixed level thorough the process of the target consumption. Thus, in a subsequent lithography alignment process, the use of the apparatus and process described in the present invention can keep the shift of the alignment or overlap marks at a fixed level.

It will be apparent to a person skilled in the art that both the foregoing general description and the following detailed description are exemplary, and are intended only to provide further explanation of the present invention as claimed.

### BRIEF DESCRIPTION OF THE DRAWINGS

FIG. 1 illustrates a film deposited in a trench portion in a lithographicalignment or overlap mark on a wafer using a conventional magnetron DC sputtering process.

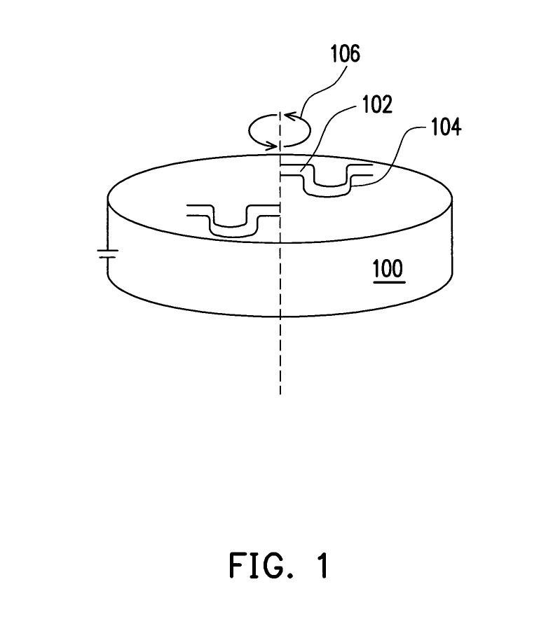

FIG. 2 is a schematic diagram illustrating a cross sectional view of a PVD apparatus, in accordance with one embodiment of the present invention.

FIG. 3 is a schematic diagram illustrating a cross sectional view of the PVD apparatus for performing out a PVD process, in accordance with one embodiment of the present invention.

FIG. 4 is a schematic diagram illustrating a cross sectional view of a deposited film that is aligned or overlapped with a trench in a wafer, in accordance with one embodiment of the present invention.

### DESCRIPTION OF THE EMBODIMENTS

The following description of the preferred embodiments of the present invention, as illustrated in the accompanying drawings, is set forth, to provide a thorough understanding of the present invention and not to limit the scope of the present invention.

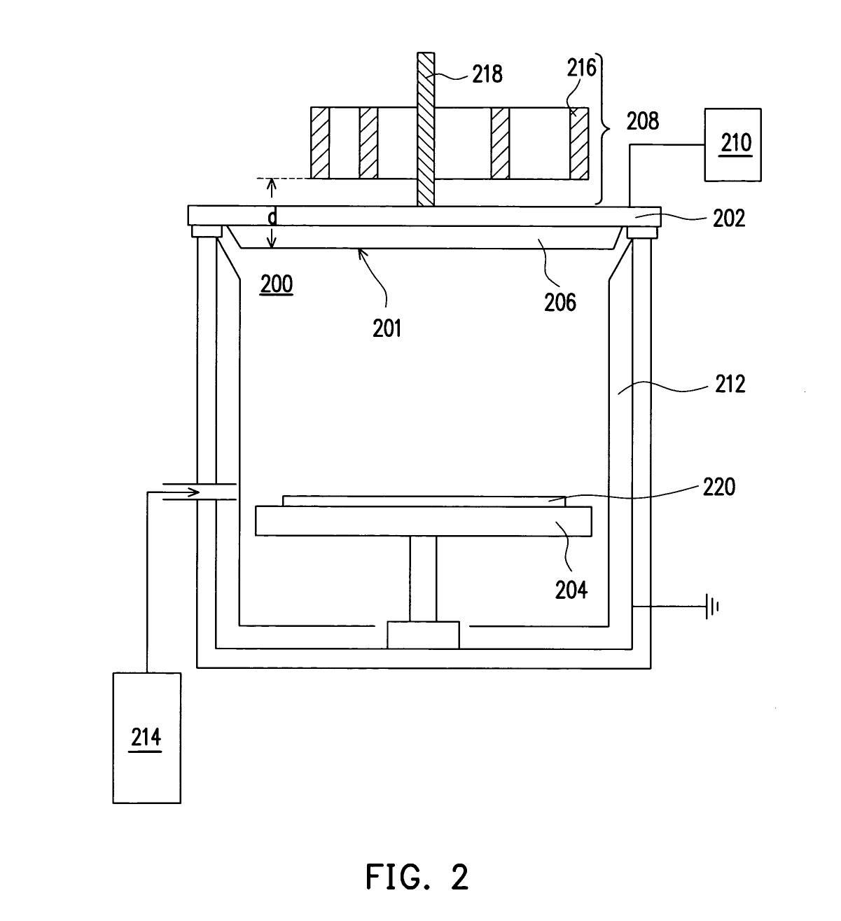

FIG. 2 is a schematic diagram illustrating a cross sectional view of a PVD apparatus, in accordance with one embodiment of the present invention. The PVD apparatus comprises a chamber 200, a target back plate 202, a wafer base 204, a target 206, a magnetron device 208, a power supply device 210, a shelter house 212, and a gas supply device 214. Magnetron device 208 includes a plurality of magnets 216 and a magnetic axle 218.

Shelter house 212 is disposed on the sidewalls and the bottom surface of chamber 200, and is not connected to wafer base 204. In one embodiment of the present invention, shelter house 212 functions as a positive pole and is grounded. Target back plate 202 is placed over a top surface of chamber 200 and is electrically connected to power supply device 210. According to one embodiment of the present invention, target back plate 202 functions as a negative pole. Wafer base 204 is disposed on the bottom surface of chamber 200 in order to support wafer 220.

Target 206 is disposed on a surface of target back plate 202 facing wafer base 204. According to one embodiment of the present invention, the target 206 is a metallic target made of metals, such as titanium, cobalt, nickel, tantalum, tungsten, aluminum, and copper.

Magnetron device 208 is placed above target 206, outside chamber 200. According to one embodiment of the present invention, the magnetron device 208 is a rotating magnetron device that can be also moved in a vertical direction. Thus, when the PVD apparatus is used in a PVD process, the position of magnetron device 208 can be adjusted along magnetic axle 218, so as to maintain a constant distance ‘d’ between the magnet of magnetron device 208 and bombardment surface 201 of target 206, and also to keep a constant magnetic field intensity induced throughout bombardment surface 201. According to another embodiment of the present invention, magnetron device 208 is a rotating magnetron device comprising an electromagnet. Thus, when the PVD apparatus described in the present invention is used in a PVD process, current intensity of the magnetron device 208 can be adjusted to keep a constant magnetic field intensity induced throughout bombardment surface 201 of target 206.

Gas supply device 214 is connected to chamber 200 through sidewall and for supplying plasma gas into chamber 200. The plasma gas is, for example, an inert gas such as argon. According to one embodiment of the present invention, the chamber 200 further comprises a second inlet for a second gas supply device (not shown in FIG. 2) for supplying a reaction gas into chamber 200. The type of reaction gas varies according to the required process. For example, for depositing a thin layer of titanium nitride, the target 206 is a titanium metal, and the reaction gas is nitrogen.

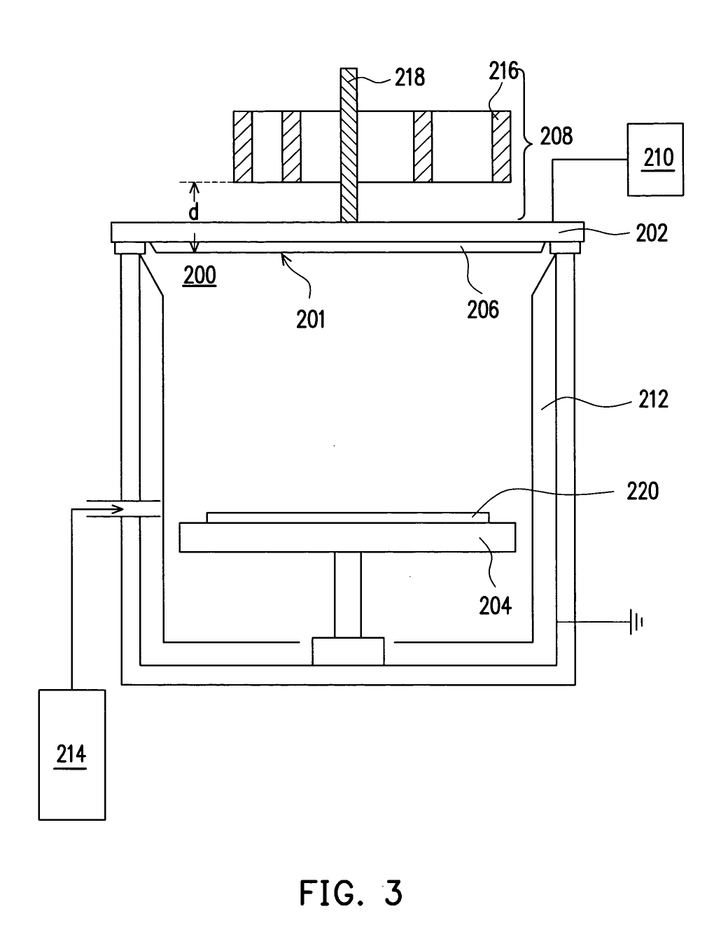

FIG. 3 is a schematic diagram illustrating a cross sectional view of the PVD apparatus for performing a PVD process in accordance with one embodiment of the present invention. The PVD process carried out using the PVD apparatus (described with reference to FIG. 2) is described in the following sections.

Wafer 220 is first placed on wafer base 204 in chamber 200.

Next, the power supply device 210 is turned on to apply a negative voltage to electrode 202, while shelter house 212 is grounded. A Plasma gas, for example, argon, is then ionized in the chamber 200 and ionized gas bombards target 206. This process of sputtering releases atoms from target 206. In addition, the rotating magnetron device 208 increases the sputtering yield and consequently increases the density of the plasma gas.

According to one embodiment of the present invention, the magnetron device 208 is a rotating magnetron device that can also be moved in a vertical direction. Thus, when the PVD apparatus described in the present invention is used for performing a PVD process, current intensity of magnetron device 208 can be adjusted to keep the induced magnetic field intensity constant over the bombardment surface 201 of target 206. Also the position of magnetron device 208 can be adjusted along magnetic axle 218, in order to maintain a constant distance d between a magnet of magnetron device 208 and bombardment surface 201 of target 206.

Referring to FIG. 3, with the increase of the thickness of the film deposited on wafer 220 and the increase in the number of wafers on which the film is deposited, the thickness of the target 206 is gradually reduced. Consequently, the magnetic field induced over bombardment surface 201 of the target 206 gradually becomes stronger. According to one embodiment of the present invention however, the position of magnetron device 208 can be adjusted in a vertical direction along magnetic axle 218. This adjustment maintains a constant distance d between a magnet of the magnetron device 208 and the bombardment surface 201 of target 206, and further keeps a constant magnetic field intensity induced throughout the bombardment surface 201. Also, in the PVD process described in the present invention, when the magnetic field induced over the bombardment surface 201 is kept constant, a Lorentz force acting on bombardment surface 201 is also kept constant. The relationship between the magnetic field intensity and Lorentz force is illustrated by the following equation:
\vec{F}=q/m(\vec{E}+\vec{v}×\vec{B})
where, F is the Lorentz force exerted on a plasma ion on bombardment surface 201 of target 206, q is the electric charge carried by the plasma ion, m is mass of the plasma ion and v is the velocity of the plasma ion. B is the magnetic field intensity induced on bombardment surface 201, and E is the electric field induced between electrode 202 and electrode 212.

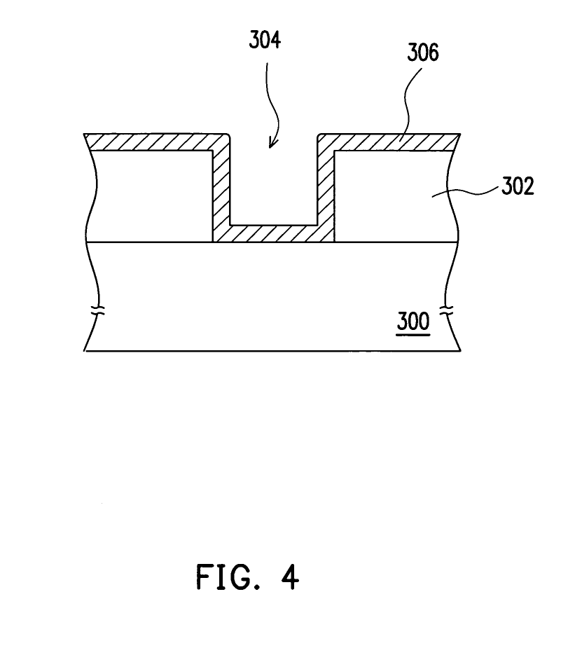

FIG. 4 illustrates a trench of an alignment mark or an overlap mark on wafer 220, which comprises a silicon substrate 300 and a dielectric layer 302 formed over substrate 300. Dielectric layer 302 has an opening 304. Referring to FIG. 4, when the PVD apparatus described in the present invention is used for performing a PVD process, the position of magnetron device 208 can be adjusted along the magnetic axle 218, in order to maintain a constant distance d between the magnet of the magnetron device 208 and the bombardment surface 201 of the target 206, and further to keep a constant magnetic field intensity induced over the bombardment surface 201. Thus, the extent of asymmetry of the asymmetric deposition of film 306 on sidewalls of opening 304 can be kept substantially unchanged. Hence, the extent of asymmetry of the asymmetric deposition is not aggregated and enhanced with the consumption of the target 206.

In accordance with another embodiment of the present invention, the magnetron device 208 is a rotating magnetron device of an electromagnet type. Thus, when the PVD apparatus described in the present invention, is used in a PVD process, the current intensity of magnetron device 208 is adjusted in order to keep the magnetic field intensity induced over bombardment surface 201 of the target 206 constant. With the increase of the thickness of the film deposited on wafer 220 and the increase in the number of wafers on which the film is deposited, the thickness of target 206 is gradually reduced. Consequently, the magnetic field induced on bombardment surface 201 of target 206 gradually becomes stronger. However, in the PVD apparatus described in the present invention, adjustment of the current intensity can be used to change the intensity of the induced magnetic field. Consequently a constant induced magnetic field intensity is maintained over bombardment surface 201. Also a constant Lorentz force is maintained. Thus, the extent of asymmetry of the asymmetric deposition of film 306 on sidewalls of opening 304 is kept unchanged, and the asymmetric deposition is not aggregated and enhanced with the consumption of target 206.

Hence, the PVD apparatus and process described in the present invention have at least the following advantages:

First, the PVD apparatus described in the present invention comprises a mobile or electromagnet-type magnetron device. Thus, when it is used for performing a PVD process, the position of the mobile magnetron device or the current intensity of the electromagnet-type magnetron device can be suitably adjusted in order to maintain a constant induced magnetic field intensity over the bombardment surface 201 of target 206. Also a constant Lorentz force exerted on plasma ions on bombardment surface 201 can be maintained. Thus, the use of the apparatus and process described in the present invention reduces the problem of aggregation of extent of asymmetry. With the use of the apparatus and process described in the present invention the extent of asymmetric deposition will not be aggregated and enhanced during the process of deposition.

Secondly, since the magnetic field intensity induced throughout bombardment surface 201 of target 206 can be maintained at a constant value, the extent of asymmetry of the asymmetric deposition is also maintained even with the gradual consumption of target 206. Thus, during a fabrication process of defining metal conducting lines, the metal conducting lines can be defined with a higher precision of alignment using the PVD apparatus and process described in the present invention. Further, the PVD apparatus and process of the present invention, when used during a process of defining metal conducting lines, is unlike prior art apparatus and process where adjusting of compensation coefficient of overlap shift is required to overcome the problem caused by shift of lithographic alignment or overlap marks during a lithographic process. Thus, the process can be simplified.

Thirdly, the PVD apparatus and process of the present invention are not limited to the embodiments disclosed above. In other words, when similar PVD apparatus and processes are used in a fabrication process comprising deposition of a film, the deposited film has the aforementioned advantages that the asymmetry of the asymmetric deposition can be kept constant if the Lorentz force felt by plasma ions on the bombardment surface of the target remains at a constant value based on electric field intensity in the chamber (E), magnetic field intensity induced over the bombardment surface of the target (B) and relevant parameters of plasma ions (q, m, and v).

It will be apparent to those skilled in the art that various modifications and variations can be made to the structure of the present invention without changing the scope or departing from the spirit of the invention. In view of the foregoing, it is intended that the present invention covers modifications and variations of this invention provided they fall within the scope of the following claims and their equivalents.

1. An apparatus for physical vapor deposition (PVD), comprising:
a chamber;
a target back plate, disposed over a top surface of the chamber;
a wafer base, disposed over a bottom surface of the chamber;
a target, disposed over a surface of the target back plate facing the wafer base; and
a mobile magnetron device, disposed outside the chamber and above the target, wherein a position of the mobile magnetron device can be adjusted during a PVD process in order to maintain a constant distance between a magnet pole of the mobile magnetron device and a bombardment surface of the target.

2. The apparatus for PVD in accordance with claim 1, further comprising a power supply device electrically connected to the target back plate.

3. The apparatus for PVD in accordance with claim 1, wherein the mobile magnetron device is a rotating mobile magnetron device.

4. The apparatus for PVD in accordance with claim 1, further comprising a gas supply device.

5. An apparatus for PVD, comprising:
a chamber;
a target back plate, disposed over a top surface of the chamber;
a wafer base, disposed over a bottom surface of the chamber;
a target, disposed over a surface of the target back plate facing the wafer base; and
an electromagnet-type magnetron device, disposed outside the chamber and above the target, wherein current intensity of the electromagnet-type magnetron device can be adjusted during a PVD process in order to maintain a constant magnetic field intensity induced over a bombardment surface of the target.

6. The apparatus for PVD in accordance with claim 5, further comprising a power supply device electrically connected to the target back plate.

7. The apparatus for PVD in accordance with claim 5, wherein the electromagnet-type magnetron device is a rotating electromagnet-type magnetron device.

8. The apparatus for PVD in accordance with claim 5, further comprising a gas supply device.

9. A process for PVD, comprising the steps of:
providing a plasma chamber comprising a mobile magnetron device, a target, a target back plate, a wafer base and a power supply device, wherein, the target is disposed on a surface of the target back plate facing the wafer base, the mobile magnetron device is disposed outside the plasma chamber and on top of the target, and the target back plate is electrically connected to the power supply device;
placing a wafer on the wafer base disposed on a bottom surface of the chamber; and
starting the power supply device and the mobile magnetron device for commencing a process of deposition of a film over a surface of the wafer, wherein during the process of deposition, a position of the mobile magnetron device is adjusted in order to maintain a constant distance between a magnet pole of the mobile magnetron device and a bombardment surface of the target.

10. The process for PVD in accordance with claim 9, wherein during the process of deposition of the film, electric charge carried by a plasma ion generated in the process of deposition of the film is q, mass of the plasma ion is m, velocity of the plasma ion is v, magnetic field intensity induced on the bombardment surface is B, electric field intensity in the plasma chamber is E, and relationship among q, m, v, B and E is as shown in the following equation:
q/m(\vec{E}+\vec{v}×\vec{B})=\vec{F}
where F is Lorentz force exerted on the plasma ion over the bombardment surface of the target, the Lorentz force (F) is maintained at a constant value during the process of depositing the film.

11. The process for PVD in accordance with claim 10, wherein the plasma ions generated during the process of deposition comprise inert gas ions.

12. The process for PVD in accordance with claim 11, wherein the inert gas ions comprise argon ions.

13. A process for PVD, comprising:
providing a plasma chamber comprising an electromagnet-type magnetron device, a target, a target back plate, a wafer base and a power supply device, wherein the target is disposed over a surface of the target back plate facing the wafer base, the electromagnet-type magnetron device is disposed outside the plasma chamber and on top of the target, and the target back plate is electrically connected to the power supply device;
placing a wafer on the wafer base; and
starting the power supply device and the electromagnet-type magnetron device for commencing a process of deposition of a film on the wafer, wherein during the process of deposition, the current intensity of the electromagnet-type magnetron device is adjusted to maintain a constant magnetic field intensity induced over a bombardment surface of the target.

14. The process for PVD in accordance with claim 13, wherein, during the process of deposition of the film, electric charge carried by a plasma ion generated in the process of deposition of the film is q, mass of the plasma ion is m, velocity of the plasma ion is v, magnetic field intensity induced on the bombardment surface is B, electric field intensity in the plasma chamber is E, and relationship among q, m, v, B and E is as shown in the following equation:
q/m(\vec{E}+\vec{v}×\vec{B})=\vec{F}
where F is Lorentz force exerted on the plasma ion on the bombardment surface of the target, the Lorentz force (F) is maintained at a constant value during the process of deposition.

15. The process for PVD in accordance with claim 14, wherein the plasma ions generated during the process of deposition comprise inert gas ions.

16. The process for PVD in accordance with claim 15, wherein the inert gas ions comprise argon ions.

17. A process for PVD, comprising:
generating an electric field and a magnetic field for a process of deposition of a film, wherein, during the process of deposition of the film, electric charge carried by a plasma ion generated in the process of deposition of the film is q, mass of the plasma ion is m, velocity of the plasma ion is v, magnetic field intensity induced on a bombardment surface is B, electric field intensity in a plasma chamber is E, and relationship among q, m, v, B and E is as shown in the following equation:
q/m(\vec{E}+\vec{v}×\vec{B})=\vec{F}
where F is Lorentz force exerted on the plasma ion on the bombardment surface of the target, the Lorentz force (F) is maintained at a constant value during the process of deposition of the film.

18. The process for PVD in accordance with claim 17, wherein the plasma ions generated during the process of deposition of the film comprise inert gas ions.

19. The process for PVD in accordance with claim 18, wherein the inert gas ions comprise argon ions.
